(19) United States
(12) Patent Application Publication
(10) Pub. No.: US 2010/0120311 A1
(43) Pub. Date: May 13, 2010

(54) METHOD FOR PROVIDING TEXTILES WITH DESENSITIZED SILVER COMPONENTS

(76) Inventors: Walter Bender, Rheinfelden (CH); Marco Bonetti, Burgdorf (CH)

Correspondence Address: O'BRIEN JONES, PLLC, 1951 Kidwell Drive, Suite 550 B, Tyson's Corner, VA, 22182, US

(21) Appl. No.: 12/516,136

(22) PCT Filed: Nov. 27, 2007
(86) PCT No.: PCT/EP2007/062884

§ 371 Date: Jan. 8, 2010

(30) Foreign Application Priority Data
Nov. 27, 2006 (EP) 06124801.9

(51) Int. Cl. B32B 5/02; B05D 1/02; B05D 1/28; A01N 59/16; C23C 16/00; D02G 3/02

(52) U.S. Cl. 442/123; 427/421.1; 427/429; 424/618; 427/248.1; 428/375

(57) ABSTRACT

A process for finishing fibers and textiles with an antimicrobially active component comprising at least one silver component desensitized by an additional component, such as pinacryptol yellow, provides durable protection of textiles against bacterial attack and discolorations of the textiles.

This invention relates to a process for antimicrobial finishing of fibers and textiles, to an antimicrobial preparation and to the fibers and textiles finished with a specific antimicrobial component. The active antimicrobial therein consists essentially of a desensitized silver component, for example silver chloride. The active antimicrobial is useful inter alia as an auxiliary for finishing fibers, yams, fibrous nonwoven webs and textiles.

Most textiles contain microbiologically degradable material. They are frequently either wholly or partly made of microbiologically degradable fibers, for example cotton, cellulose (e.g., viscose and Tencel), hemp, flax, linen, silk, acetate or wool. Textiles made of synthetic fibers such as for example polyester, polyacrylonitrile, polyamide (e.g., aramid, Nomex, Kevlar, nylon-6, nylon-6,6) or polypropylene also become colonized by bacteria, in particular when treated with finishing agents, for example softeners, hydrophobicizers, antistats and/or binders, or pick up microbiologically degradable material in use, for example organic substances from the environment.

Colonization with microorganisms such as bacteria can have a negative impact on the performance characteristics of textiles as well as their appearance. In addition, the release of metabolism products in the case of bacteria, for example, can cause unpleasant odor nuisances and pose a health hazard. It is therefore necessary to finish fibers or textiles with preservatives, in particular with antimicrobial components, in order that colonization by microorganisms such as bacteria, for example, may be controlled.

However, difficulties frequently arise when trying to finish the fiber or textiles with active antimicrobials, these difficulties concerning not only the finishing operation as such but also phenomena due to the finish.

The textile industry expects the antimicrobial components used for finishing fibers and textiles to meet high requirements. For example, the as-finished fibers or textiles are dried at temperatures of 100 to 130° C. and subsequently treated at temperatures up to 180° C., for example in order that “relaxation” may be achieved and polymeric components may be fully polymerized. In the process, the antimicrobial component may be destroyed, or the high evaporation rate of the antimicrobial component may lead to losses of active ingredient. The active antimicrobial ingredient remaining on the fiber after finishing can be washed off in practical use of the textile in laundering operations, owing to the large surface area of the textiles and the low thickness of the layer of finish. This washoff results in a further loss of active ingredient over time. Furthermore, in the case of light-sensitive antimicrobial preparations, the influence of light can lead to decomposition of the active antimicrobial ingredients. After the finishing has taken place, the interaction of the antimicrobial component with other constituents causes observable discolorations of the textiles.

There are descriptions of effective antimicrobially active ingredients in the prior art which have a low rate of evaporation and also largely stay on the fiber in a laundering operation. Frequently, however, antimicrobially active ingredients which are satisfactory as such are less suitable for the finishing of textiles because of toxic effects or other disadvantages. For example, skin irritations may arise when textiles which have been finished to be antimicrobial are made up (for example cut, sewing, etc.) because skin contact occurs even in the case of such textiles which otherwise do not come into contact with the human body during the intended use.

German patent application DE-A 43 39 374 relates to a process for producing fibers finished with an antimicrobially active component. The antimicrobially active component used is a silver-containing inorganic microbicide which is used in a treatment solution together with a discolorization inhibitor. This discolorization inhibitor consists of a benzotriazole derivative.

International patent application WO 1996/01119 describes an antimicrobial composition which, in addition to silver ions, also contains a stabilizing component. The technical teaching in WO 1996/01119 has for its purpose to achieve a photostabilization of the antimicrobial composition that can be used in various sectors. A polyether polymer is used as well as an addition of stabilizing anions. The antimicrobial compositions thus stabilized are useful in the production of foamed plastics for example.

EP-A 0 446 993 discloses organic substances useful for desensitization in relation to photographic developers. Specifically the compound pinacryptol yellow (6-ethoxy-1-methyl-2-(3-nitrostyryl)quinolinium methylsulfonate) is described as a desensitizing component in relation to photographic development. Other documents similarly disclose dyes for photography, for example the compound pinacryptol green.

Owing to the above-described volatilization of the biocidally or antimicrobially active ingredients, it is frequently necessary to use high concentrations of sometimes costly actives having high minimum inhibitory concentration (MIC) values in order that, despite the losses of active ingredient, the desired antimicrobial effect, sufficient to meet practical requirements, may be met, which entails appreciable costs. Furthermore, the high use concentrations and the high losses of antimicrobial active impact the environment during production and use of these products.

There is therefore a constant need for the development of antimicrobial preparations that satisfy as many of the following criteria as possible:
They shall be appliable using the customary standard methods of the textile industry,
They shall be compatible with as many other textile effects as possible,
They shall be very durable to washing, including particularly in the case of textiles composed of polyester or polyamide,
They shall have little if any influence on the hand of textiles,
The antimicrobially active components shall ideally have been notified to the authorities (for example under EPA and under BPD),
They shall have a competitive price, i.e., be simple to manufacture;
The antimicrobially active components shall be durable and should be usable in an environmentally benign manner.

It is an object of the present invention to provide a process and a preparation for the antimicrobial finishing of textiles or fibers that substantially avoid the above-recited disadvantages. The environmental impact and the costs of finishing the textile to control harmful microorganisms shall be reduced. The antimicrobial effect of the microbicides used for finishing the fiber or textiles shall be ensured for a very long period.

Antimicrobial preparations in particular and biocidal agents in general have long been used in many areas of everyday life, for example for controlling harmful bacteria, fungi or algae. Having regard to the ever growing demands on antimicrobial components, for example with regard to cost, health and environmental protection aspects, further development of these known products is necessary.

It has been known for hundreds of years that silver and silver compounds can have a germ-killing or antimicrobial effect. However, the use of silver compounds as antimicrobial agents is for various reasons limited to certain fields. Silver formulations described for preservation purposes include for example elemental silver in colloidal form, dispersions of nanoparticulate silver, silver compounds such as silver oxide or inorganic and organic silver salts. The silver or silver compounds may also be embedded in carrier materials, for example silicas, titanium dioxide, zeolites or glass.

Preservation by means of silver has the disadvantage, among others, that silver compounds, particularly in the presence of reducing compounds and under the influence of light, can lead to discolorations. The use of higher silver concentrations heightens the risk of discoloration, which is undesirable in the field of finishing fibers and textiles in particular. In addition, silver-containing formulations are also costly when compared with many other commercially available antimicrobial formulations, which distinctly limits their use in practice.

Examples of common fields of use of silver as an antimicrobial agent are coatings for household appliances, the field of medicine and pharmacy and also water treatment. Silver is also known in the field of industrial preservation, for example in relation to adhesives, sealants, coatings and plastics. DE-A 103 46 387 cites silver as an example of possible preservative, and describes the use of silver-containing preparations for antimicrobial finishing of hard and soft surfaces. This reference also describes the use of silver ions or silver on carriers, in solutions and dispersions for the treatment of textiles and other materials.

The present invention has for its object to provide a novel biocidal composition comprising a stabilized or desensitized silver component, that provides durable protection for fibers and textiles. The present invention further has for its object to use the abovementioned antimicrobial component for a process for finishing fibers and textiles. The durable protection for fibers and textiles shall also reduce the impact on the environment and lower the costs of controlling harmful microorganisms.

The silver component and the desensitizing component may preferably be formulated together but in principle also separately. Similarly, the components can be applied to the fiber or textile simultaneously or else, if appropriate, in succession.

We have found that the abovementioned object is achieved according to the present invention by providing a process for finishing fibers and/or textiles with a biocidally active component comprising a silver component desensitized by an additional component and also, optionally, one or more further antimicrobial components.

The present invention provides in particular a process for finishing fibers and/or textiles with an antimicrobially active component comprising a silver component desensitized by an additional component and also, optionally, one or more further antimicrobial components, wherein the additional component used comprises at least one compound from the group of the quinoline derivatives.

Preferably, the antimicrobially active component applied to the fibers or textiles is a silver component desensitized by an additional component comprising pinacryptol yellow.

Frequently, an antimicrobially active component used comprises a silver salt as silver component.

In one embodiment of the present invention, an antimicrobially active component used comprises a silver salt formed in situ as silver component and pinacryptol yellow as additional component.

In one embodiment of the present invention, an antimicrobially active component used comprises a silver salt as silver component and, as desensitizing component, at least one quinoline derivative and additionally a benzotriazole derivative.

The present invention also provides a process characterized in that the silver component is used in an amount of 0.0001% by weight to 1.5% by weight, based on the total weight of the fibers or textiles (including for example 0.0001 to 0.5% by weight).

One embodiment of the present invention utilizes a process characterized in that the desensitizing component used is a quinoline derivative in an amount of 0.1 ppm to 500 ppm, based on the total weight of the fibers or textiles.

One embodiment of the present invention utilizes a process characterized in that an antimicrobially active component used comprises a water-insoluble silver salt as silver component and, as desensitizing component, at least one quinoline derivative and a benzotriazole derivative in an amount (based on the total weight of the fibers or textiles) of 0.5 ppm to 2500 ppm.

One embodiment of the present invention utilizes a process characterized in that the water-insoluble silver component comprises one or more salts from the group of the chlorides, bromides, iodides, sulfates and tosylates.

The present invention further provides a process characterized in that the water-insoluble silver component comprises a silver chloride prepared in situ from silver nitrate and metal chloride.

The present invention also provides a process characterized in that the desensitizing component comprises pinacryptol yellow as sole component or else a combination of pinacryptol yellow with at least one other desensitizing component.

The present invention further provides a process characterized in that the process for finishing the fibers and/or textiles comprises a padding process, exhaust process, foam application process, coating process or spraying process.

The present invention further provides an antimicrobial preparation for finishing fibers and/or textiles with an antimicrobially active component, comprising as antimicrobially active component at least one silver component, a desensitizing additional component and also optionally one or more auxiliary and additive materials, wherein the additional component used comprises at least one compound from the group of the quinoline derivatives.

The present invention further provides a preparation comprising 0.01% to 10% of a silver component and 0.001% to 2% of pinacryptol yellow.

The present invention further provides antimicrobially finished fibers and textiles obtained by following a process as described above.

The present invention further provides antimicrobially finished fibers and textiles characterized in that they consist essentially of cotton, cellulose, silk, polyester, polyamide, other synthetic or natural fibers or of mixtures thereof.

The present invention also provides antimicrobially finished textiles characterized in that they comprise woven fabrics, knitted fabrics, fibrous nonwoven webs or yarns.

The present invention further very generally provides for the use of a preparation as described above for protecting fibers and textiles against attack by bacteria.

The present invention further provides for the use of a preparation characterized in that it comprises a silver salt and, as desensitizing component, at least one quinoline derivative and a benzotriazole derivative, for protecting fibers and textiles against attack by bacteria.

Preference is given to using an antimicrobially active component comprising as silver component at least one silver salt and as additional component at least one organic, desensitizing component.

A further embodiment of the present invention utilizes an antimicrobially active component comprising as silver component at least one water-insoluble silver salt and as desensitizing component at least one quinoline derivative.

Quinoline derivatives are, in particular, substituted quinoline compounds and salts thereof which have desensitizing properties. As preferred representatives of this group there are used the compounds pinacryptol yellow (6-ethoxy-1-methyl-2-(3-nitro-β-styryl)quinolinium methylsulfate; CAS 25910-85-4) and other salts of the compound. Quinoline derivative, however, is also to be understood as subsuming pinacryptol green (1,3-diamino-5-phenyl-phenazinium chloride; CAS 19220-)7-8) and pinacryptol white. Pinacryptol yellow is preferably used, however.

A further embodiment of the present invention utilizes an antimicrobially active component comprising as silver component at least one water-insoluble silver salt and as desensitizing component at least one quinoline derivative and/or a benzotriazole derivative.

Benzotriazole derivatives are, in particular, the compounds or salts of the general formula (I)

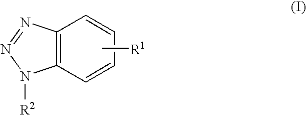

where R1 is hydrogen or a C1-C4-alkyl group,

and R2 is hydrogen or a metal, preferably an alkali metal.

The preferred benzotriazole derivative is 1,2,3-benzotriazole which per se is not endurable to laundering.

Instead of the benzotriazole derivative of formula (I) it is in principle also possible to use any other UV stabilizer. It is also possible to use the quinoline compound in combination with a benzotriazole derivative and a further UV stabilizer.

A further embodiment of the present invention uses the silver component in an amount of 0.0001% by weight to 0.5% by weight, in particular 0.001 to 0.05% by weight, based on the total weight of the fibers or textiles.

The antimicrobial compositions of the present invention preferably comprise the silver component (the silver compounds, for example) in certain amounts. In this connection, and in the context of the present invention, it is always the content of silver (Ag⁰) which is used as reckoning basis. When, for example, a preparation of the present invention comprises 100 mg of silver chloride per kg, its silver content will be 73.53 mg per kg, i.e., 0.007% by weight.

Textile pre- or aftertreatment compositions which contain an antimicrobial component of the present invention and can be in solid, liquid or flowable form, as a gel, powder, granulate, paste or spray, contain silver (reckoned as Ag) in amounts which are preferably in the range from 0.00005% to 5% by weight and particularly in the range from 0. 1% to 1.5% by weight. A further embodiment uses 0.0001% to 0.5% by weight of silver and particularly 0.001% to 0.5% by weight, based on the composition.

The amount in which the quinoline derivative is used as desensitizing component is preferably in the range from 0.1 ppm to 500 ppm, particularly in the range from 1 ppm to 150 ppm, based on the total weight of the fibers or textiles.

The ratio (weight) between silver component and desensitizing component in the antimicrobially composition is for example in the range from 0.1:1 to 1:500. It can also be in the range from 1:10 to 1:500 and preferably in the range from 1:10 to 1:100.

A particular embodiment of the present invention is characterized in that an antimicrobially active component used comprises at least one water-insoluble silver salt as silver component and, as desensitizing component, at least one quinoline derivative and additionally a benzotriazole derivative. The additional use of benzotriazole is advantageous with some fiber types in particular.

The benzotriazole derivative is preferably used in an amount, based on the total weight of the fibers or textiles, of 0.5 ppm to 2500 ppm, in particular of 5 ppm to 500 ppm, including for example from 5 ppm to 150 ppm (particularly 20 ppm to 50 ppm in a padding process).

The water-insoluble silver component may comprise for example one or more salts from the group of the chlorides, bromides, iodides, sulfates and tosylates. In this connection, the term “water-insoluble” is not to be understood as meaning that no ions pass into a solution, but is to be understood as meaning that the salt has only minimal solubility in water.

In one embodiment of the present invention, the silver salt is formed in situ, for example by direct reaction of a soluble silver salt (such as silver nitrate) with some other soluble salt (sodium chloride for example).

A further embodiment of the present invention utilizes a process wherein the desensitizing component is a combination of the compounds pinacryptol yellow and benzotriazole. These components can be used as such or else preformulated as solutions or dispersions together or separately.

The process of the present invention may comprise for example a padding process, exhaust process, foam application process, coating process or spraying process.

The present invention also provides antimicrobially finished fibers or textiles obtained by following one of the processes described. The antimicrobially finished fibers or textiles may comprise for example fibers or textiles consisting essentially of cotton, cellulose, silk, polyester, polyamide or other synthetic or natural fibers.

The antimicrobially finished textiles may preferably comprise woven fabrics, knitted fabrics, fibrous nonwoven webs or yarns, but other textiles can be finished as well.

A further embodiment of the present invention provides for the use of a composition comprising a silver component desensitized by an additive, for protecting fibers and textiles against attack by microorganisms. The composition itself is likewise part of the subject matter of the present invention, and this composition may already contain the components or else be provided as a kit of components.

The preparation of the present invention contains for example (based on the total weight of the preparation) 0.01% to 10%, in particular 0.1% to 3% of a silver component and 0.001% to 2%, in particular 0.01% to 0.5% of a desensitizing component (for example of the compound pinacryptol yellow). The preparation can also contain solvents (such as water and/or alcohols) and auxiliary materials (such as surfactants or wetting and binding agents).

More particularly, the present invention provides for the use of the abovementioned compositions when they contain a water-insoluble silver salt and, as desensitizing component, at least one quinoline derivative and/or a benzotriazole derivative, for protecting fibers and textiles against attack by bacteria, including Gram-positive and Gram-negative bacteria.

It is known in the prior art that silver and silver ions exert a blocking effect on thiol enzymes in microorganisms and thus exert a high bactericidal effect. The terms “antimicrobial effect” and “antimicrobially active component” are herein used in the usual meaning in the art, as represented for example by K. H. Wallhäusser in “Praxis der Sterilisation, Desinfektion—Konservierung: Keimidentifizierung—Betriebshygiene” (5th edition—Stuttgart; New York: Thieme, 1995).

In accordance with the present invention, the silver component is preferably used in the form of its compounds, for example in the form of the abovementioned silver salts. Preparations according to the present invention can contain the silver component in the form of various particle sizes. They can contain the silver particles (for example silver chloride particles) for example with particle sizes of for example 0.001 to 100 μm, including for example from 0.04 to 80 μm.

In one particularly preferred embodiment, the silver component used comprises nanoparticles having particle sizes ranging from 0.001 to 0.1 μm, preferably from 0.002 to 0.05 μm and particularly from 0.004 to 0.01 μm. The particles in question can also be wholly or partly present in colloidal form. The antimicrobial particles may be included in the preparation in the already preformulated form, or be freshly produced.

The processibility of the silver component having low particle sizes can be improved by applying the silver component to carrier materials. To this end, suitable carrier materials can be for example impregnated with colloidal solutions or mixed with finely divided silver compounds. It is also possible to granulate the silver component together with the carrier materials in the presence of suitable granulation aids. Useful carrier materials include, in particular, builder or framework materials, for example zeolites. In addition to these it is also possible for highly porous materials, such as silicas, for example fumed silicas, bentonites, polymeric materials or diatomaceous earth (“kieselguhr”) to serve as carrier materials, and also ceramic materials capable of ion exchange, for example based on zirconium phosphate, or else glasses. Similarly, activated carbon, apatite, phosphates activated carbon, activated alumina, silica gel, hydroxylapatite, zirconium phosphate, titanium phosphate, potassium titanate, antimony oxide hydrate, bismuth oxide hydrate, zirconium oxide hydrate and hydrotalcite are possible in principle.

The process for applying silver ions to such inorganic compounds is not restricted to certain processes. There are various application processes, for example a process through physical or chemical adsorption, a process through ion exchange reaction, a process through use of a binder, a process through incorporation of a silver compound into an inorganic compound and a process through forming a thin layer of the silver compound on the surface of an inorganic compound by a technique for forming a thin layer, such as vapor sedimentation, dissolving on and precipitating or sputtering.

Such composite particles formed from carrier material and silver component may optionally include further ingredients. It will be found advantageous to use for example activating noble metals such as gold, which activates the antimicrobial effect of the silver component.

The described process for finishing fibers and/or textiles with an antimicrobially active component comprising a silver component desensitized by an additional component can be used in the production of antimicrobial fibers and textiles. The antimicrobial fiber obtained by this process does not lead to any discoloration.

The antimicrobially finished fibers can be used as starting product for diverse materials for various fiber products such as clothing (for example ladies outerwear, menswear, childrenswear, sports and leisure apparel, workwear, socks, stockings and underwear), bedding (for example bed covering and sheets), home furnishings, seat covers, upholstery fabrics, textiles for shoes, shower curtains, filters, carpets, protective articles (for example masks and bandages) and the like.

A fiber finished with an antimicrobial component (hereinafter referred to as antimicrobial fiber) is optionally subjected in the course of the process to various treatment steps, such as pulling, rinsing, dyeing, bleaching, blend fiber spinning and weight reduction, and it is treated with various treatment solutions, for example textile oil, aqueous alkali metal hydroxide solution, bleaching agents and detergents. In the course of the treatment, a portion of the silver ions present in the antimicrobial component dissolves in the treatment solutions or reacts with various components of the treatment solutions, which can cause discoloration of the antimicrobial fiber in the conventional processes.

To protect antimicrobial preparations from discoloration, the use of a stabilizer has already been proposed in the literature. For example, the stabilizers described in EP-A 02 880 63, for antimicrobial resin compositions, each contain a) an antimicrobial zeolite which bears silver ions, and b) a resin, and also c) benzotriazole compounds, oxanilide compounds, salicylic acid compounds, hindered amine compounds and/or hindered phenol compounds. When these stabilizers are added to a fiber production resin and the resin is spun into an antimicrobial fiber, however, it is later not possible to adequately suppress the discoloration of the antimicrobial fiber.

This is not even realizable when the antimicrobial fiber is treated with various treatment solutions in the treatment steps, or when the spinning solution used for producing the antimicrobial fiber contains a large amount of solvent.

It is an object of the present invention to develop an antimicrobial fiber production process which does not lead to any discoloration in the various fiber treatment steps.

The present invention provides a process for producing an antimicrobial fiber wherein this fiber undergoes, during or after production, essentially no discoloration due to use of the treatment solutions or solely due to the spinning solution.

The base fiber used in the present invention can be for example a natural or synthetic (manufactured) fiber. The natural fiber preferably contains vegetable fibers, such as cotton, hemp, flax, coir and reed. In principle, animal fibers, such as goat's hair, mohair, cashmere, camel hair and silk and mineral fibers are finishable with the process.

Examples of manufactured fibers are cellulose fibers such as viscose fiber, protein fibers, such as casein fiber and soybean fiber, regenerated, semisynthetic fibers, such as regenerated silk yarn or alginate fiber. Finishable synthetic fibers are in particular: polyamide fiber, polyester fiber and their mixtures. In principle, the process of the present invention can also be applied to polypropylene fibers, polyvinyl fiber, polyacrylic fiber, polyurethane fiber, polyethylene fiber, polyvinylidene fiber and polystyrene fiber. The process can also be applied to blend fibers, however.

For antibacterial use in textiles, silver in ionic form can be incorporated into synthetic fibers during the spinning operation for example. Such products are already on offer from various producers and are based on silver compounds such as salts or silver oxide bound on various carrier materials such as titanium oxide, zinc oxide or glassy carriers or those composed of ceramic. Ion exchangers and zeolites are likewise used as carrier material.

These products are very often on offer in the form of masterbatches, a concentrated form of the active compound in a polymeric carrier which is compatible with the plastic of the end product in the entire production operation, for example the fiber. The intermediate stage of a masterbatch makes industrial processing appreciably easier, since the diluting from the pure active compound to the concentration in the end product is done in two or more stages. In addition, the active compound is in a form in which it is easier to handle and easier to integrate in the industrial operation of fiber production.

However, the incorporation of such products does present technical difficulties. The biocidal components must have a consistency or constitution such that the number of broken ends does not increase at the spinning stage. This can be influenced for example via the choice of the maximum size, the size distribution, the geometry of the biocidal particles and their wetability by the fiber material. In practice, however, thin or very thin fibers, microfibers, quickly come up against limits when the active components do not melt under the process conditions, which is not the case with the silver compounds nor with the abovementioned carriers.

A further critical aspect of the antimicrobial finishing of fibers is fiber abrasion, which can shorten the service life of the spinning machine through the use of antimicrobial components. Such silver components can also influence the post-spinning finishing steps, such as the dyeing operation for example. Flexibility in the spinning of the fibers also has particular importance. It is difficult, for example, to handle a plurality of fiber grades with regard to the incorporated properties. Product changes on the equipment used in the present age are frequently uneconomical and should therefore be avoided.

The metering of additives during the spinning operation is difficult since not only the pure synthetic fiber but also blend yams and blend fabrics are produced from the primary spun product. Particularly when natural fibers are used as further components, the textiles produced therefrom will only be partially and therefore insufficiently antimicrobial.

Also known are coatings of any kind of textiles with metallic silver or the use of yarns consisting of or containing silver.

The disadvantages of these technical solutions include the specific processing, the intrinsic color of the textiles, the different behaviors of the fibers in aftertreatments such as dyeing, the haptics of such textiles, the nonuniform antimicrobial properties and the high price for these textiles.

A further aspect of the present invention is the finishing of textiles in the final finishing operation wherein textile properties such as haptics, hydrophobicity, hydrophilicity, soil repellency, ironability, sewability, thread slip resistance and others are fine tuned. Among these are also the hygiene finishes (for example for antibacterial performance). The advantage of applying an antibacterial hygiene finish in this step is that only textiles where such a finish is desired are actually finished in this way. There are thus no stray effects as would be the case if the entire output of a spinning mill had to be finished. Technically, it is a decisive advantage of the abovementioned process that the entire textile is finished and not just a portion thereof, for example a certain type of fiber. When applying a finish in the final finishing operation, the finish ends up wherever it is supposed to be effective, which in the case of antimicrobial finishes is normally at the surface.

The disadvantages of applying an antimicrobial finish in the final finishing operation are the often poor durability of the finishes in laundering. This comes about when finishing chemicals are incapable of reacting with the textile or combine on the textile, by reaction with themselves or other building blocks, to form macromolecules which are then permanent by virtue of crosslinking and/or mass. In the case of antimicrobial components, there should be a certain minimum availability in order that they may be able to act at all. Therefore, these active compounds must not be fully bound to or in the fiber. This technical requirement is at odds with the desire to achieve a very large number of wash cycles for a finished article while the antimicrobial effect remains at a consistent, high level.

Various antimicrobial components based on silver (or silver ions) are already on the market. These include for example various types such as Nano Ag from Air Products, Silpure from Thomson Research Associates, Dorafresh AG from Dohmen, diverse JMAC grades from Clariant, Rucobac AGP from Rudolf Chemie.

However, these products all have to be applied to textiles together with polymeric binders in order that a certain durability of the finish to laundering may be obtained. One reason is that the silver salts are applied to a carrier and have to be fixed on the textile together with this carrier since the affinity of these particles without fixing is not sufficient to achieve a comparatively high permanence to laundering.

ALPHASAN from Milliken (USA), a product with silver ions on an ion exchanger, is used as an example to demonstrate wash durability in U.S. Pat. No. 6,821,936. It is shown that when the ALPHASAN is applied without binder the antimicrobial efficacy, tested to AATCC 100-1993 against Staphylococcus aureus, decreases after just a single wash, carried out to AATCC 130-1981, by more than two powers of ten compared with the unwashed sample. When the product is applied together with binder, up to 10 wash cycles can be achieved with partly good antibacterial results.

When for example the AmpZ200 product from DuPont, a product with titanium dioxide as carrier for the silver ions, is used instead of ALPHASAN, wash durability is poor. The loss of antibacterial performance is even more drastic in the case of the ZEOMIC AJ 80H product, likewise described in U.S. Pat. No. 6,821,936.

In-house tests with commercial products have shown that some of the known products tend to discolor the textiles finished therewith and directly exposed to sunlight. Products based on metallic silver are in some instances themselves already dark gray to black, which is clearly visible on light-colored or even white textiles finished therewith.

There are already several proposals in the literature for achieving stability to discoloration of silver salts on textiles. DE-A 43 39 374 describes the use of benzotriazole and derivatives thereof for the stabilization of silver compounds of the general formula AgₚM¹_{q}M²₂(PO₄)₃×n H₂O, M¹ is selected from the group consisting of alkali metal ions, alkaline earth metal ions, ammonium ions and hydrogen ions and M² is a tetravalent metal selected from the group consisting of Ti, Zr and Sn. p, which ultimately indicates the concentration of the silver ion, is set to a range from 0.01 to 0.5. In addition, silver ions on an inorganic ion exchanger are summarizingly said to be the active component. This discolorization inhibitor is applied to the textile in the spin bath of the fiber production process.

JP 2003212993 (Chugai Shashin, published 07.30.2003) achieves the stabilization of silver compounds to discolorations (inter alia on textiles for apparel) by using copolymers having hydroxylamino groups.

It is an object of the present invention to provide a composition based on silver ions which is appliable to textiles by means of padding processes and exhaust processes for example and where the color undergoes no change or virtually no change when the textile is exposed to sunlight.

The stabilization of the antimicrobial component shall in principle also be appliable without polymeric or copolymeric binder systems. Furthermore, wash durability shall amount to at least 20 wash cycles. The washes are carried out to the EN ISO 6330 (6A) standard at 40° C. Washing is done for example with the ECE 77 colorfastness detergent, tested via the antibacterial effect against Staphylococcus aureus (ATCC 6538) to JISL 1902:2002 and/or to ASTM E 21-49.

The improvement in wash durability was tested hereinbelow using very small silver salt particles in some instances. The examples which follow illustrate the invention. Some commercially available auxiliaries were used, including the following:

Table of commercially available products used hereinbelow

| | | | Composition/ |
|---|---|---|---|
| Product | Purpose | Source | description |
| Appretan N | Prepolymer textile | Manufacturer: | Acrylate copolymer dispersion |
| N 92111 liq. | binder for soft hand | Clariant | |
| Appretan TS | Hand modifier | Manufacturer: | Nonionic polyvinyl acetate |
| liq. | | Clariant | dispersion |
| Appretan N | Produces soft, elastic | Manufacturer: | Solvent-free, anionic, aliphatic |
| N 52281 liq. | hand | Clariant | polyester polyurethane |
| | | | dispersion |
| Arkofix | Extremely low- | Manufacturer: | Modified dimethyloldihydroxy- |
| NES liq. c | formaldehyde | Clariant | ethyleneurea derivative |
| | crosslinker for low-iron | | |
| | or iron-free finishing of | | |
| | cellulose fibers | | |
| Catalyst | Catalyst for | Manufacturer: | Mixture of metal salts and |
| NKS liq. | crosslinking of reactant | Clariant | organic acids |
| | crosslinkers | | |
| Cassurit | Self-crosslinking resin | Manufacturer: | Highly etherified N-methoxy- |
| HML liq. | for enhanced | Clariant | methylmelamine component |
| | permanence | | |
| Solusoft | Highly concentrated, | Manufacturer: | nonionic microemulsion of |
| MW liq. c | non-yellowing | Clariant | modified polysiloxane |
| | permanent silicone | | |
| | elastomer for softening | | |
| | of all fiber species | | |
| Hydroperm HV | Permanent softener for | Manufacturer: | Aqueous emulsion |
| liq. | textile | Clariant | |
| Hydroperm | Thermoreactive | Manufacturer: | Aqueous emulsion |
| RPU liq. | polyurethane softener | Clariant | |
| | for textiles | | |
| NUVA HPC | Fluorocarbon for | Manufacturer: | Perfluoroacrylate copolymers |
| FL liq. | hydrophobicization/ | Clariant | |
| | oleophobicization | | |
| NUVA HPS FL | Fluorocarbon for | Manufacturer: | Perfluoroacrylate copolymers |
| liq. | hydrophobicization/ | Clariant | |
| | oleophobicization | | |
| NUVA HPU | Fluorocarbon for | Manufacturer: | Perfluoroacrylate copolymer |
| FL liq. | hydrophobicization/ | Clariant | |
| | oleophobicization | | |
| NUVA TTC FL | Fluorocarbon for | Manufacturer: | Perfluoroacrylate/polyurethane |
| | hydrophobicization/ | Clariant | dispersion |
| | oleophobicization | | |
| Pekoflam | Permanent flame | Manufacturer: | Nonionic phosphoric ester |
| DPN 1 liq. | retardant for cotton | Clariant | |
| Pekoflam | Semipermanent flame | Manufacturer: | Mixture of ammonium |
| HSD liq. | retardant | Clariant | polyphosphate and urea |
| Pekoflam | Permanent flame | Manufacturer: | Mixture of cyclic di- and |
| PES liq. | retardant for PES | Clariant | triphosphonates |
| Hostapal MRN | Wetting agent | Manufacturer: | Nonionic silicone- and solvent- |
| | | Clariant | free wetting, washing & |
| | | | cleaning agent; polyglycol ether |
| | | | derivative |
| Hostapal NRW | Wetting agent, | Manufacturer: | Nonionic polyglycol ether |
| | surfactant, dispersant | Clariant | |
| Hostapal MRN | Wetting agent, | Manufacturer: | Nonionic wetting agent |
| | surfactant, dispersant | Clariant | |
| Fluowet UD | Fluorinated wetting | Manufacturer: | Wetting agent particularly |
| liq. | agent | Clariant | suitable for textile finishes with |
| | | | fluorocarbons for water-, oil- |
| | | | and soil-repellant finishes |
| Velustrol P40 | Polyethylene wax | Manufacturer: | Aqueous emulsion |
| | emulsion as softener for | Clariant | |
| | textiles | | |
| Pinacryptol | Photodesensitizer, | Manufacturer: | Technical/industrial product |
| yellow | prevents the reduction | Honeywell | |
| | of silver salts to | | |
| | metallic silver | | |
| Silver nitrate | Water-soluble salt as | Dealer: | |
| | starting material for | Johnson | |
| | silver chloride | Matthey | |
| Benzotriazole | Free-radical scavenger, | Dealer: | |
| | stabilizes the silver | Clariant | |
| | chloride together with | | |
| | the pinacryptol yellow | | |
| | in the commercial | | |
| | product and in the | | |
| | liquor at application | | |
| Komplexon III | Complexing agent for | Dealer: | Ethylenediaminetetraacetic acid |
| or Idranal III | metal ions | Fluka/Riedel- | disodium salt dihydrate |
| | | de-Haën | |
| Gelatin | Gelatin from hog hide | Dealer: | 1% gelatin is dissolved in hot |
| | | Fluka/Riedel- | water |
| | | de-Haën | |
| Imbentin C | Nonionic surfactant | Manufacturer: | Ethoxylated C12-C15 fatty |
| 125/55/90 | | Kolb, CH- | alcohol 90% in water, cloud |
| | | Hedingen | point 55° C. |
| Hydroxylamine | Free-radical scavenger | Dealer: | |
| hydrochloride | | Fluka/Riedel- | |
| | | de-Haën | |
| Veegum F | Thickener | Manufacturer: | Colloidal magnesium |
| | | R. T. Vanderbilt | aluminosilicate |
| | | Company, | |
| | | Inc., USA | |
| Rhodopol 23 | Thickener | Manufacturer: | Heteropolysaccharide |
| | | Rhodia | |
| Propylene | Solvent | Dealer: | |
| glycol | | Brenntag | |
| Magnesium | Crosslinking catalyst | Dealer: | |
| chloride | | Brenntag | |
| ECE 77 | Standardized detergent | Dealer: | |
| detergent | for colorfastness testing | EMPA | |
| | | St. Gallen | |

### COMPARATIVE EXAMPLE 1

An attempt was made to precipitate silver chloride from dissolved silver nitrate by addition of a sodium chloride solution directly in an application solution such that the silver chloride particles are small enough to achieve improved adherence on the textile than with a silver chloride or other silver salts applied directly on a carrier material. A comparative test was carried out with silver nitrate without precipitation with sodium chloride solution.

For applications of the hereinbelow recited examples, 7.87 g of silver nitrate were dissolved in 100 ml of deionized water. This solution was used as stock solution and used just diluted or diluted and admixed with further chemicals. This was done with the objective of improving the distribution of silver chloride on the textile and also with the objective of improving the fixing of the silver chloride on the textile. It was further done with the objective of obtaining more stable baths for application.

Except in the case of example 2, the silver chloride was precipitated from the application baths (in situ) by addition of a 20% aqueous sodium chloride solution.

3.3 g of silver nitrate solution (7.87 g of silver nitrate ad 100 g of water) are dissolved in 243 g of water and admixed with 3.3 g of sodium chloride solution (20% aqueous NaCl solution) by stirring. This bath, which had a very pronounced tendency to separate, is applied, immediately after it has been prepared, to a woven cotton fabric having a basis weight of 198 g/m² using a padder. The pick-up was 88%. Therefore, the concentration of silver ions on the textile is reckoned to be about 580 ppm. The fabric was dried in a tenter at 120° C. for two minutes.

### COMPARATIVE EXAMPLE 2

3.3 g of silver nitrate solution (7.87 g of silver nitrate ad 100 g of water) are dissolved to form a solution of 200 g of water and 5.0 g of Komplexon III (ethylenediaminetetraacetic acid disodium salt) are added with stirring. This is then followed by the successive addition of 1.0 g of Sandozin MRN (wetting agent from Clariant), 17.5 g of Appretan TT 50 (anionic, solvent-free, aliphatic polyester polyurethane dispersion, binder from Clariant, for a soft elastic hand of the textile) and then 2.0 g of acetic acid (80%). The pH of the liquor is 6.4. At the end a further 21.2 g of water are added.

This bath, which is very stable during application, was in turn applied to the same cotton fabric as described in example 1 by means of a padder. The pick-up was 76%. Therefore the concentration of silver ions on the textile is reckoned to be about 500 ppm. The fabric was dried in a tenter at 120° C. for two minutes and subsequently cured at 150° C. for 90 seconds. Both the textile and the bath discolor in indoor light.

### COMPARATIVE EXAMPLE 3

220 g of deionized water are initially charged and while stirring
5.0 g of Komplexon III are dissolved therein and
1.0 g of Sandozin NRW (polyglycol ether, manufacturer: Clariant) is added as a wetting agent.
17.5 g of Appretan N 92111 (acrylate copolymer dispersion with soft hand from Clariant) were added as a binder and then
3.3 g of silver nitrate solution and subsequently
3.0 g of sodium chloride solution were added with stirring.

This bath, which is stable during application, was in turn applied to the same cotton fabric as described in example 1 by means of a padder. The pick-up was 72%. Therefore the concentration of silver ions on the textile is reckoned to be about 475 ppm. The fabric was dried in a tenter at 120° C. for two minutes and subsequently cured at 150° C. for 90 seconds. Both the textile and the bath discolor in indoor light.

### COMPARATIVE EXAMPLEs 4 AND 5

These examples were carried out similarly to example 3 except that the Appretan N 92111 was replaced by, respectively, the product Appretan TT 50 and the crosslinker Arkofix NDF (melamine resin from Clariant) together with Catalyst NKS.

Almost all samples discolored in daylight even indoors and behind window glass within a few minutes to several hours. The sample of example 1 took several hours to discolor. Similarly, the liquors discolored quickly in that silver was precipitated on the walls of the vessels used for storage.

The discolorations of the textile samples were in the hues of orange, aubergine to violet and not (as actually expected) black, as is known from metallic finely divided silver. It is known that extremely finely divided metallic silver (comprising nanoparticles) is no longer black but corresponds to the abovementioned color.

The samples were used to carry out the wash trials of up to 20 cycles as described above irrespective of the severe discoloration which is not acceptable for commerical practice (except for very dark articles or for articles which are not seen in use, for example fibers or fibrous nonwoven webs for fiberfill material).

The washed samples were then used to carry out the microbiological tests. These tests were positive. The kill rate for Staphylococcus aureus (ATCC 6538), tested by following the Japanese microbe-counting method JISL 1902:2002, equalled at least two powers of ten even after 20 washes. This result was achieved for all finishes with and without binder/crosslinker.

The results were thus already superior or comparable to the values reported in U.S. Pat. No. 6,821,936 (Milliken & Company; 2004) after just one wash.

### EXAMPLE 6

A prolonged inhibition of the discoloration of precipitated silver chloride is achievable for example through the use of the components described hereinbelow.

The “freshly precipitated silver chloride” is so light-stable that it can be applied to a carrier and the fabric finished therewith immediately discolors in sunlight neither in the washed state nor in the unwashed state. However, discoloration does come about after a certain time as a result of the silver ions being reduced to elemental silver by the action of light. It was found that the use of desensitized silver salts can prevent or at least substantially reduce durable discoloration.

The following are examples of materials used for desensitization photography in which films are exposable, albeit at a retarded rate:
a) ammonium hexachlororhodate(III), CAS number: 15336-18-2,
b) pinacryptol dyes such as pinacryptol green or pinacryptol white, or
c) pinacryptol yellow, IUPAC: 6-ethoxy-1-methyl-2-(3-nitro-β-styryl)quinolinum methylsulfate having the empirical formula C₂₁H₂₂N₂O₇S, a relative molecular mass of 446.47 g/mol and the CAS number: 25910-85-4. Photoemulsions are further also produced with gelatin in photography.

Since textiles are exposed to daylight intensively and for very long periods and also are frequently washed, it was completely surprising that the abovementioned desensitizing components can also be used for textiles.

In accordance with the example,
1.57 g of silver nitrate are dissolved in
45 g of 1% gelatin solution (porcine gelatin dissolved in hot deionized water).
50 g of Appretan N 92111 (a Clariant acrylate copolymer forming a soft film) are added.
2.0 g of a pinacryptol yellow solution in water saturated at about 20° C. and
2.0 g of 20% sodium chloride solution are added with stirring.

### EXAMPLE 7

84.4 g of 1% gelatin solution (porcine gelatin dissolved in hot deionized water) are initially charged, admixed with
1.57 g of silver nitrate and
5.0 g of pinacryptol yellow solution in water saturated at about 20° C. and
5.0 g of Imbentin C 125/55/90 (an ethoxylated C-12/15 fatty alcohol of CAS number 68131-39-5 from Kolb, Hedingen),
5.0 g of pinacryptol yellow solution in water saturated at about 20° C. and
3.0 g of 20% sodium chloride solution and subsequently
1.0 g of acetic acid 80% are added with stirring.

The disperse and yellow products were padded onto woven cotton fabrics having a basis weight of 198 g/m². The product of example 6 is applied to a woven polyester fabric having a basis weight of 220 g/m².

Specifically, the product of example 6 was used to prepare an application liquor comprising 20 g/l of the product and applied to the polyester fabric by padding. A pick-up of 40% gave a 0.8% concentration of the product of example 6.

The product of example 7 was applied to the woven cotton fabric. Specifically, the application solutions comprising 15 to 16 g/l of the product of example 6 and 0.7 to 1.4 g/l of Sandozin NRW wetting agent were applied to the woven cotton fabric without further textile chemicals and together with 70 g/l of Appretan TT 50 or Appretan N92111.

The pick-up was between 76 and 80%, so that 1% of the product comprising silver chloride was applied in each case. The textiles were dried at 140° C.

These textile samples were subsequently hung up outdoors for a week. The samples all displayed pink spots and in some instances a reddish discoloration of the entire sample. Nevertheless, the samples were washed 20 times and subsequently tested for their antibacterial efficacy. The polyester sample showed a fairly modest kill rate while the cotton samples without binder showed a kill rate for Staphylococcus aureus ATCC 6538 in the test to JISL 1902:2002 of 2.5 powers of ten and the samples with the binders each showed a kill rate of above four powers of ten in the same test.

The products of the examples likewise discolored (in not-to-be-applied form) very quickly in the glass bottles. Thus, the stabilization of the preparation per se was still not sufficient. Nor was the stability of the products themselves sufficient, since they separated off too quickly.

### EXAMPLE 8

In the following experiments, the amount of gelatin was raised to a value of up to 2% and the amount of the pinacryptol yellow solution was raised distinctly, to a value of up to 10% (in the case of a solution saturated at 20° C.). The light stability both of the textiles and of the experimental products improved, but was still not satisfactory. The rate of settling of the dispersed particles in the products was too high.

To further improve the photodesensitization, the concentration of the pinacryptol yellow was raised to a value as high as 0.1% of the total amount of the formulation and in addition the compound benzotriazole (CAS number 95-14-7) was used as an additional stabilizer. In addition to gelatin, further products were tested as thickeners for the formulation. For instance, Stabilize QM carboxymethylcellulose (CMC) was tested, reacting visibly with silver nitrate but not with precipitated silver chloride, with which the production of a formulation with CMC as thickener works. Also tested were Bentone EW, copolymeric binders from Clariant such as Appretan N92111, Appretan TS, an aqueous polyvinyl acetate dispersion and Appretan TT 50.

In addition to the use of the quinoline derivative pinacryptol yellow as stabilizer alone and together with benzotriazole, testing was also done with just benzotriazole at up to amounts of 5 g/g of silver ions and also hydroxylamine hydrochloride (CAS number: 5470-11-1) up to amounts of 3 g/g of silver ions.

However, the two compounds benzotriazole and hydroxylamine hydrochloride are not capable, in the concentration used, of permanently suppressing either the discoloration of the formulation itself or the discoloration of the textile due to the applied formulation. Likewise poorish results were obtained when the concentration of the pinacryptol yellow was lowered to below 0.025% for example, irrespective of whether benzotriazole was or was not included in the formulation.

### EXAMPLE 8b

In the following experiment
930 g of water were deionized,
1.0 g of pinacryptol yellow was added with stirring and dissolved as far as possible,
16.0 g of silver nitrate were added, followed by stirring at room temperature for 5 minutes and then with stirring
   35.0 g of sodium chloride solution prepared from 20 g of sodium chloride containing <0.001% of higher halides (bromide and iodide) and dissolved in 80 g of deionized water, were added.
      To the yellow, fine dispersion are added
   4.0 g of Rhodopol 23 heteropolysaccharide dispersant, CAS number: 11138-66-2, and
      14.0 g of Veegum F colloidal magnesium aluminosilicate from R.T. Vanderbilt Company, Inc. as dispersing assistant.

A mixer (dissolver) was used to disperse the mixture for 30 minutes to form a yellow, low-viscosity dispersion which is stable at room temperature.

This formulation was used to perform padded applications to woven fabric composed of cotton, polyamide and polyester such that 1% of the formulation (on weight of fiber) was applied. These samples were directly exposed in daylight for three days. The polyamide sample exhibited an extremely weak pink coloration, while the other fabrics did not exhibit any discoloration.

The abovementioned preparation can also be prepared and used without the dispersing assistants.

To improve the stability of the dispersion and to improve the ease of incorporation of the formulation into the application bath, a small amount of propylene glycol was included in the formulation as further solvent in addition to water. In lieu of propylene glycol it is also possible to use further alcohols or commercially available wetting agents or surfactants alone or in admixture. To further improve the lightfastness not only of the product itself but particularly of the applied product, benzotriazole was used in addition to the quinoline derivative pinacryptol yellow. These measures did not prove to be absolutely essential, but do improve the utility and stability of the product. There is a gain of consistency for application.

### EXAMPLE 9

Example 9 describes the preparation of a formulation suitable for industrial manufacture.
84.3 kg of deionized water are initially charged to a steel vessel open at the top.
100 g of pinacryptol yellow are added while stirring with a dissolver.
Dissolve as far as possible at 600 rpm for 15 minutes and disperse the remainder.
500 g of benzotriazole are added and processed with the dissolver for a further five minutes.
1600 g of silver nitrate are added, followed by stirring with the dissolver at room temperature for 5 minutes, and then within about two minutes a solution of
700 g of sodium chloride in
2.8 kg of deionized water is added.
   After a further five minutes by the dissolver, the yellow, fine dispersion has added to it in succession
400 g of Rhodopol 23 heteropolysaccharide, CAS number: 11138-66-2, and
1400 g of Veegum F colloidal magnesium aluminosilicate from R.T. Vanderbilt Company, Inc., by sprinkling.
8.2 kg of propylene glycol are added.

A dissolver was used to disperse the mixture a m for 30 minutes to form a yellow, low-viscosity, very readily meterable, stable dispersion.

The formulation of example 9 was used to carry out various applications. The applications by padding for each were carried out by initially charging the water and adding the wetting agent. The wetting agent serves to minimize the length of the wetting sector in the padder, but does not prove to be necessary. Sandozin MRN liq. (also known as Hostapal MRN) was used for example.

Acetic acid was used, so that the applications were carried out in the weakly acidic range, as corresponds to one standard of the textile industry, but is likewise not strictly necessary for the formulation described. In some instances, additional textile chemicals for other textile effects were included in the liquor, examples being polymer binders, crosslinkers, softeners and fluorocarbons. The formulation, prepared as described above, was then stirred into this aqueous liquor, in each case as last component. These liquors were applied with a padder in a completely standard way to the textiles to be finished. The samples were dried and partly cured on a tenter, although the formulations of the present invention themselves do not require curing. But curing can be necessary, to crosslink and/or fix the other textile chemicals in the individual finishes and is apparent from the technical documentation for the particular products.

Textiles thus finished were tested for their antibacterial action against Staphylococcus aureus ATCC 6538 with and without pretreatment. These tests were carried out in accordance with the standards JISL 1902:2002 and, respectively, ASTM E 21-49.

The results for both tests are reported in terms of the decadic logarithm of the kill rate after 18 hours of incubation. The kill rate is based on the microorganism count of the inoculum or to be more precise on a control sample after 18 hours of incubation. The number of microorganisms is counted after the plating out of the dilution series and subsequent incubation of the plates.

A very good antibacterial effect gives values of 2 or higher, while a kill rate of 1.5 or higher up to 2 is satisfactory.

Smaller values are unsatisfactory for finished samples and come within the range of variation of the two test methods.

The textiles were pretreated by means of sunlight, achieved through outdoor exposure of the test samples. To this end, the test samples were hung up outdoors under a canopy and each assessed by visual inspection. The samples were tested following a varying number of wash cycles (in accordance with EN ISO 6330 (6A) at 40° C., carried out with the ECE 77 colorfastness detergent); and in some instances the samples were exposed to daylight after washing.

The textiles used were in each case woven fabrics composed of cotton having a basis weight of 198 g/m², polyamide jersey having a basis weight of 160 g/m² and Trevira polyester having a basis weight of 220 g/m², or a Dacron 54 spun at 120 g/m², or the 9046 article from Tersuisse having a basis weight of 230 g/m² and the 1880 article from Interlock having a basis weight of 160 g/m².

The results which follow show that the results do not depend on the type of polyester used.

### EXAMPLEs 10 TO 15

| | Example | |
|---|---|---|
| | 10 | 11 |
| Sample | Cotton, gabardine, | Cotton, gabardine, |
| Recipe | 200 g/m² | 200 g/m² |
| Sandozin MRN liq. [g/l] | 1 | 1 |
| Appretan N 92111 [g/l] | — | 70 |
| Formulation to example 9 [g/l] | 15 | 15 |
| pH adjusted with acetic acid to | 4.5 | 4.5 |
| Application data (padder; tenter) | | |
| Pick-up (g of liquor picked up:g of dry textile) | 0.71 | 0.71 |
| Drying conditions [° C.; s] | 120; 120 | 120; 120 |
| Curing conditions [° C.; s] | — | 160; 90 |
| Example 9 formulation concentration [%] | 1 | 1 |
| | log kill rate for Staphylococcus aureus | |
| Tests after pretreatment of sample | ATCC 6538 to JISL 1902:2002 | |
| Original state (unwashed, unexposed) | >4.9 | >4.9 |
| 30 washes at 40° C., 4 day exposure | >4.9 | >4.9 |
| 50 washes at 40° C., 4 day exposure | 2.5 | >5.3 |
| | Visual assessment in each case after | |
| | 4 days daylight exposure after the | |
| | particular number of washes reported | |
| Unwashed, immediately | no discoloration | no discoloration |
| Unwashed, after 4 days sunlight (SL) | no discoloration | no discoloration |
| 1 wash, after 4 days SL | no discoloration | no discoloration |
| 2 washes, after 4 days SL | no discoloration | no discoloration |
| 3 washes, after 4 days SL | no discoloration | no discoloration |
| 10 washes, after 4 days SL | no discoloration | no discoloration |
| 20 washes, after 4 days SL | no discoloration | no discoloration |
| 30 washes, after 4 days SL | no discoloration | no discoloration |
| | Example | |
| | 12 | 13 |
| Sample | Trevira polyester | Trevira polyester |
| Recipe | 220 g/m² | 220 g/m² |
| Sandozin MRN liq. [g/l] | 1 | 1 |
| Appretan N 92111 [g/l] | — | 120 |
| Formulation to example 9 [g/l] | 35 | 35 |
| pH adjusted with acetic acid to | 4.2 | 4.2 |
| Application data (padder; tenter) | | |
| Pick-up (g of liquor picked up:g of dry textile) | 0.30 | 0.30 |
| Drying conditions [° C.; s] | 120; 120 | 120; 120 |
| Curing conditions [° C.; s] | — | 160; 90 |
| Example 9 formulation concentration [%] | 1 | 1 |
| | log kill rate for Staphylococcus aureus | |
| Tests after pretreatment of sample | ATCC 6538 to JISL 1902:2002 | |
| Original state (unwashed, unexposed) | >4.9 | >4.9 |
| 30 washes at 40° C., exposed | 2.4 | 3.1 |
| 50 washes at 40° C., day exposed | −0.2 | 2.5 |
| | Visual assessment in each case after | |
| | 4 days daylight exposure after the | |
| | particular number of washes reported | |
| Unwashed, immediately | no discoloration | no discoloration |
| Unwashed, after 4 days sunlight (SL) | no discoloration | no discoloration |
| 1 wash, after 4 days SL | no discoloration | no discoloration |
| 2 washes, after 4 days SL | no discoloration | no discoloration |
| 3 washes, after 4 days SL | no discoloration | no discoloration |
| 10 washes, after 4 days SL | no discoloration | no discoloration |
| 20 washes, after 4 days SL | no discoloration | no discoloration |
| 30 washes, after 4 days SL | no discoloration | no discoloration |
| | Example | |
| | 14 | 15 |
| Sample | Jersey polyamide | Jersey polyamide |
| Recipe | 160 g/m² | 160 g/m² |
| Sandozin MRN liq. [g/l] | 1 | 1 |
| Appretan N 92111 [g/l] | — | 70 |
| Formulation to example 9 [g/l] | 14 | 14 |
| pH adjusted with acetic acid to | 4.1 | 4.4 |
| Application data (padder; tenter) | | |
| Pick-up (g of liquor picked up: g of dry textile) | 0.82 | 0.82 |
| Drying conditions [° C.; s] | 120; 120 | 120; 120 |
| Curing conditions [° C.; s] | — | 160; 90 |
| Example 9 formulation concentration [%] | 1.1 | 1.1 |
| | log kill rate for Staphylococcus aureus | |
| Tests after pretreatment of sample | ATCC 6538 to JISL 1902:2002 | |
| Original state (unwashed, unexposed) | 3.1 | >4.9 |
| 30 washes at 40° C., exposed | 3.3 | not tested |
| 50 washes at 40° C., exposed | 3.6 | >5.3 |
| | Visual assessment in each case after | |
| | 4 days daylight exposure after the | |
| | particular number of washes reported | |
| Unwashed, immediately | no discoloration | no discoloration |
| Unwashed, after 4 days sunlight (SL) | no discoloration | no discoloration |
| 1 wash, after 4 days SL | no discoloration | no discoloration |
| 2 washes, after 4 days SL | no discoloration | no discoloration |
| 3 washes, after 4 days SL | no discoloration | no discoloration |
| 10 washes, after 4 days SL | no discoloration | no discoloration |
| 20 washes, after 4 days SL | no discoloration | no discoloration |
| 30 washes, after 4 days SL | no discoloration | no discoloration |

Typical examples for use of textiles finished as described above are clothing textiles, in particular workwear, uniforms and particularly leisure and sportswear, bedding, textile wallcoverings, seat covers, upholstered furniture and carpets, tablecloths, fabrics for umbrellas, home textiles such as cleaning cloths, wiping cloths, towels, any articles made of terry, and also textile playthings.

### EXAMPLES 16 TO 20

Example 10 was repeated to finish woven cotton fabric with 0.3, 0.4, 0.5, 0.6 and 0.8% of the formulation of example 9. The difference was that the pH was not adjusted but 1 g/l of 80% acetic acid was added in each case.

The tests against Staphylococcus aureus ATCC 6338 were carried out after 30 washes to EN ISO 6330 (6A) at 40° C. Log kill rate results were within the customary range of variation of the method, from 2.6 to 3.8, and hence excellent, even at distinctly lower use concentrations of silver ions than in the preceding examples, where the concentration was in each case around 100 ppm of silver ions based on the mass of finished textile.

### EXAMPLES 21 TO 25

Example 11 was repeated to finish woven cotton fabric with 0.3, 0.4, 0.5, 0.6 and 0.8% of the formulation of example 9.

The difference was that the pH was not adjusted but 1 g/l of 80% acetic acid was added in each case. The amount of Appretan N 92111 binder was left constant at 70 g/l. The tests against Staphylococcus aureus ATCC 6338 were carried out after 30 washes to EN ISO 6330 (6A) at 40° C. The log kill rate results were within the customary range of variation of the method, from 3.2 to >4.9, and hence excellent. Good results were also achieved with the selected binder at use concentrations of 30 to 80 ppm of silver ions, reckoned from the use concentration and the pick-up.

### EXAMPLES 26 TO 31

Example 12 was repeated to finish woven polyester fabric with 0.3, 0.4, 0.5, 0.6 and 0.8% of the formulation of example 9. The difference was that the pH was not adjusted but 1 g/l of 80% acetic acid was added in each case. The tests against Staphylococcus aureus ATCC 6338 were carried out after 20 and 30 washes to EN ISO 6330 (6A) at 40° C. No sample achieved a good result after 30 wash cycles. After 20 wash cycles, the log kill rate results were within the customary range of variation of the method, but a considerable 2.2 at just 0.3% of the formulation of example 9 and even 2.6 at 0.4% of the formulation.

These results are excellent for woven polyester fabric, a product based on silver salt and applied without binder in postfinishing.

### EXAMPLES 32 TO 36

Example 13 was repeated to finish woven polyester fabric with 0.3, 0.4, 0.5, 0.6 and 0.8% of the formulation of example 9. The difference was that the pH was not adjusted but 1 g/l of 80% acetic acid was added in each case. The amount of Appretan N 92111 binder was left at a constant 120 g/l. The tests against Staphylococcus aureus ATCC 6338 were carried out after 30 washes to EN ISO 6330 (6A) at 40° C. The log kill rate results were within the customary range of variation of the method, but values of at least 3.0 were achieved.

### EXAMPLES 37 TO 41

Example 14 was repeated to finish polyamide jersey with 0.3, 0.4. 0.5, 0.6 and 0.8% of the formulation of example 9. The difference was that the pH was not adjusted, but 1 g/l of 80% acetic acid was added in each case. The tests against Staphylococcus aureus ATCC 6338 were carried out after 20 washes to EN ISO 6330 (6A) at 40° C. However, the samples did not achieve the desired kill rate values.

### EXAMPLES 42 TO 46

Example 14 was repeated to finish polyamide jersey with 0.3, 0.4, 0.5, 0.6 and 0.8% of the formulation of example 9. The difference was that the pH was not set, but 1 g/l of 80% acetic acid was added in each case. The amount of Appretan N 92111 binder was left at a constant 70 g/l. The tests against Staphylococcus aureus ATCC 6338 were carried out after 20 and 30 washes to EN ISO 6330 (6A) at 40° C.

The samples with 0.6% and 0.8% of the formulation according to example 9 achieved good values after 30 washes. However, the range of variation was considerable. Testing against Staphylococcus aureus ATCC 6538 P instead of against the standard microorganism in these tests, Staphylococcus aureus ATCC 6538, both the concentrations of 0.6 and 0.8% of the inventive formulation of example 9 give good values in all tests, i.e., above 2 for log kill rate and a value of 3.1 with 0.5% of the formulation even after 20 washes, but admittedly just 0.5 after 30 washes.

The polyamide fabric used proved to be a difficult-to-finish material in all experiments. This holds with regard to the wash durability as well as with regard to discoloration in sunlight.

### EXAMPLES 47 TO 50

| | Example | | | |
|---|---|---|---|---|
| | 47 | 48 | 49 | 50 |
| Textile | Dacron 54 spun polyester | | | |
| | about 120 g/m² | | | |
| Recipe | | | | |
| Sandozin MRN liq. [g/l] | 1.0 | 1.0 | 1.0 | 1.0 |
| Acetic acid 80% [g/l] | 1.0 | 1.0 | 1.0 | 1.0 |
| Appretan N 92111 [g/l] | — | 70 | — | 70 |
| Formulation to example 9 [g/l] | 9.0 | 9.0 | 14.0 | 14.0 |
| Application data (padder; tenter) | | | | |
| Pick-up [%] (100 × g of liquor | 75 | 74 | 73 | 75 |
| picked up:g of dry textile) | | | | |
| Curing conditions [° C.; s] | 150; 45 | 150; 45 | 150; 45 | 150; 45 |
| Example 9 formulation | 0.67 | 0.66 | 1.02 | 1.05 |
| concentration [%] | | | | |
| | log kill rate for | | | |
| Pretreatment of sample for | Staphylococcus aureus ATCC | | | |
| antibacterial tests | 6538 to JISL 1902:2002 | | | |
| Original state (unwashed) | >4.6 | >4.6 | 3.0 | >4.6 |
| 10 washes at 40° C. | 2.6 | 2.6 | 2.6 | 3.5 |
| 20 washes at 40° C. | 2.3 | 2.3 | 2.0 | 3.7 |
| 30 washes at 40° C. | 1.4 | 0.5 | 0.7 | 1.6 |

### EXAMPLES 51 TO 54

| | Example | | | |
|---|---|---|---|---|
| | 51 | 52 | 53 | 54 |
| Textile | Trevira polyester at about 220 g/m² | | | |
| Recipe | | | | |
| Sandozin MRN liq. [g/l] | 1.0 | 1.0 | 1.0 | 1.0 |
| Acetic acid 80% [g/l] | 1.0 | 1.0 | 1.0 | 1.0 |
| Appretan N 92111 [g/l] | — | 120 | — | 120 |
| Formulation to example 9 [g/l] | 14.0 | 14.0 | 23.0 | 23.0 |
| Application data (padder; tenter) | | | | |
| Pick-up [%] (100 × g of liquor | 48 | 43 | 48 | 46 |
| picked up:g of dry textile) | | | | |
| Curing conditions [° C.; s] | 150; 45 | 150; 45 | 150; 45 | 150; 45 |
| Example 9 formulation | 0.67 | 0.60 | 1.10 | 1.05 |
| concentration [%] | | | | |
| | log kill rate for | | | |
| Pretreatment of sample for | Staphylococcus aureus ATCC | | | |
| antibacterial tests | 6538 to JISL 1902:2002 | | | |
| Original state (unwashed) | >4.0 | >4.0 | >4.0 | >4.0 |
| 10 washes at 40° C. | >4.0 | >4.0 | >4.0 | >4.0 |
| 20 washes at 40° C. | >4.0 | >4.0 | >4.0 | >4.0 |
| 30 washes at 40° C. | 1.1 | 3.1 | 1.6 | >4.0 |

### EXAMPLES 55 TO 58

| | Example | | | |
|---|---|---|---|---|
| | 55 | 56 | 57 | 58 |
| Textile | Tersuisse Art. 9046 polyester | | | |
| | at about 230 g/m² | | | |
| Recipe | | | | |
| Sandozin MRN liq. [g/l] | 1.0 | 1.0 | 1.0 | 1.0 |
| Acetic acid 80% [g/l] | 1.0 | 1.0 | 1.0 | 1.0 |
| Appretan N 92111 [g/l] | — | 70 | — | 70 |
| Formulation to example 9 [g/l] | 9.0 | 9.0 | 14.0 | 14.0 |
| Application data (padder; tenter) | | | | |
| Pick-up [%] (100 × g of liquor | 69 | 78 | 77 | 73 |
| picked up:g of dry textile) | | | | |
| Curing conditions [° C.; s] | 150; 45 | 150; 45 | 150; 45 | 150; 45 |
| Example 9 formulation | 0.67 | 0.66 | 1.02 | 1.05 |
| concentration [%] | | | | |
| | log kill rate for | | | |
| Pretreatment of sample for | Staphylococcus aureus ATCC 6538 | | | |
| antibacterial tests | to JISL 1902:2002 | | | |
| Original state (unwashed) | >4.9 | 3.2 | 2.8 | >4.9 |
| 10 washes at 40° C. | 3.6 | 2.9 | 2.5 | 3.8 |
| 20 washes at 40° C. | 3.3 | 2.8 | 2.1 | 3.1 |
| 30 washes at 40° C. | 1.3 | 2.5 | 1.4 | 2.8 |

### EXAMPLES 59 TO 62

| | Example | | | |
|---|---|---|---|---|
| | 59 | 60 | 61 | 62 |
| Textile | Interlock Art. 1880 polyester | | | |
| | at about 160 g/m² | | | |
| Recipe | | | | |
| Sandozin MRN liq. [g/l] | 1.0 | 1.0 | 1.0 | 1.0 |
| Acetic acid 80% [g/l] | 1.0 | 1.0 | 1.0 | 1.0 |
| Appretan N 92111 [g/l] | — | 70 | — | 70 |
| Formulation to example 9 [g/l] | 8.0 | 9.0 | 14.0 | 14.0 |
| Application data (padder; tenter) | | | | |
| Pick-up [%] (100 × g of liquor | 77 | 85 | 78 | 90 |
| picked up:g of dry textile) | | | | |
| Curing conditions [° C.; s] | 150; 45 | 150; 45 | 150; 45 | 150; 45 |
| Example 9 formulation | 0.61 | 0.68 | 1.01 | 1.17 |
| concentration [%] | | | | |
| | log kill rate for | | | |
| Pretreatment of sample for | Staphylococcus aureus ATCC 6538 | | | |
| antibacterial tests | to JISL 1902:2002 | | | |
| Original state (unwashed) | >4.7 | >4.7 | >4.7 | >4.7 |
| 10 washes at 40° C. | 3.4 | >4.7 | >4.7 | >4.7 |
| 20 washes at 40° C. | 0.2 | 3.2 | 1.9 | 3.3 |
| 30 washes at 40° C. | 0.9 | 1.4 | 1.3 | 2.0 |

Typical examples for use of textiles finished as described above are clothing textiles, in particular workwear, uniforms and particularly leisure and sportswear, bedding, textile wallcoverings, seat covers, upholstered furniture and carpets, tablecloths, fabrics for umbrellas, sunshades and visual protection.

### EXAMPLES 63 AND 64

Experiments with easy-iron finishes based on crosslinked melamine resins applied to cotton

| | Example | |
|---|---|---|
| | 63 | 64 |
| Sample | Cotton, gabardine, | Cotton, gabardine, |
| Recipe | 200 g/m² | 200 g/m² |
| Arkofix NES liq. (crosslinker) [g/l] | 50 | 50 |
| Magnesium chloride (crosslinking cat.) [g/l] | 7.5 | 7.5 |
| Ceraperm MW liq. (softener) [g/l] | 30 | 30 |
| Formulation to example 7 [g/l] | 15 | — |
| Formulation to example 9 [g/l] | — | 15 |
| pH measured | 4.5 | 4.4 |
| Application data (padder; tenter) | | |
| Pick-up (g of liquor picked up:g of dry | 0.70 | 0.72 |
| textile) | | |
| Drying conditions [° C.; s] | 120; 120 | 120; 120 |
| Curing conditions [° C.; s] | 160; 90 | 160; 90 |
| Example 9 formulation concentration [%] | 1.05 | 1.1 |
| | log kill rate for Staphylococcus aureus | |
| Tests after pretreatment of sample | ATCC 6538 to JISL 1902:2002 | |
| Original state (unwashed, unexposed) | >4.9 | >4.9 |
| 10 washes at 40° C. | >4.9 | >4.9 |
| 20 washes at 40° C. | >4.9 | >4.9 |
| 30 washes at 40° C. | >4.9 | >4.9 |
| | Visual assessment in each case after | |
| | 7 days daylight exposure after the | |
| | particular number of washes reported | |
| Unwashed, immediately | no discoloration | no discoloration |
| Unwashed after 7 days sunlight (SL) | no discoloration | no discoloration |
| 1 wash, after 7 days SL | no discoloration | no discoloration |
| 2 washes, after 7 days SL | no discoloration | no discoloration |
| 3 washes, after 7 days SL | no discoloration | no discoloration |
| 10 washes, after 7 days SL | no discoloration | no discoloration |
| 20 washes, after 7 days SL | no discoloration | no discoloration |
| 30 washes, after 7 days SL | no discoloration | no discoloration |

These experiments were also carried out with further formulations, the preparation of which is not explicitly described herein, for example with a formulation with 10% of pinacryptol solution saturated at 20° C., a formulation with 10% of pinacryptol solution saturated at 20° C. and 0.5% of benzotriazole, and a formulation with 1.5% of carboxymethylcellulose as thickener. All these formulations provided very good wash durability and did not show any discoloration when applied as described in the recipe of examples 63 and 64.

Typical examples for use of textiles finished as described above are easy care finish clothing textiles such as shirts, blouses, home textiles such as tablecloths and napkins.

Also tested were applications of the formulation according to example 9 together with fluoro-carbons and polymeric binders. To this end, various fluorocarbons from Clariant were tested. Specifically they are Nuva TTC, a perfluoroacrylate/polyurethane dispersion, Nuva HPS liq. and Nuva HPC, both perfluoroacrylate copolymers and Nuva HPU, a perfluoroalkylacrylic copolymer.

### EXAMPLES 65 AND 66

| | Example | |
|---|---|---|
| | 65 | 66 |
| Sample | Cotton, gabardine, | Cotton, gabardine, |
| Recipe | 200 g/m² | 200 g/m² |
| Fluowet UD liq. (fluorinated wetter) [g/l] | 5.0 | 5.0 |
| Acetic acid 80% [g/l] | 0.5 | 0.5 |
| Nuva TTC [g/l] | 60 | 60 |
| Appretan N 92111 | — | 70 |
| Formulation to example 9 [g/l] | 15 | 15 |
| pH measured | 4.5 | 4.4 |
| Application data (padder; tenter) | | |
| Pick-up (g of liquor picked up:g of dry textile) | 0.72 | 0.73 |
| Curing conditions [° C.; s effective] | 150; 60 | 150; 60 |
| Example 9 formulation concentration [%] | 1.08 | 1.1 |
| | log kill rate for Staphylococcus aureus | |
| Tests after pretreatment of sample | ATCC 6538 to ASTM E 21-49 | |
| Original state (unwashed, unexposed) | >4.9 | >4.9 |
| 10 washes at 40° C. | >4.9 | >4.9 |
| 20 washes at 40° C. | >4.9 | >4.9 |
| | Visual assessment in each case after 7 | |
| | days daylight exposure after the particular | |
| | number of washes reported | |
| Unwashed, immediately | no discoloration | no discoloration |
| Unwashed, after 7 days sunlight (SL) | no discoloration | no discoloration |
| 1 wash, after 7 days SL | no discoloration | no discoloration |
| 2 washes, after 7 days SL | no discoloration | no discoloration |
| 3 washes, after 7 days SL | no discoloration | no discoloration |
| 10 washes, after 7 days SL | no discoloration | no discoloration |
| 20 washes, after 7 days SL | no discoloration | no discoloration |

The examples were all carried out in a similar manner. On the Trevira polyester, the concentrations of the fluorocarbons and of the binder were raised to respectively 90 and 100 g/l, so that the amounts applied remain comparable to the cotton fabric. On the polyamide, the same concentrations were used as on the cotton fabric. All samples exhibited an outstanding antibacterial effect at up to 20 wash cycles. In the unwashed state, all samples exhibited 100%, i.e., complete, water repellency in the AATCC 22 spray test.

Typical examples for use of textiles finished as described above are clothing textiles, in particular workwear, uniforms and water-repellent leisure and sportswear, bedding, textile wallcoverings, seat covers, upholstered furniture and carpets, tablecloths, fabrics for umbrellas, sunshades and visual protection.

Applications of the formulation according to example 9 together with flame retardants were also tested. To this end, various flame retardants from Clariant were tested. On cotton, they were applied together with a crosslinker. Specifically they are Pekoflam DPN 1, a nonionic phosphoric ester and Pekoflam HSD liq., a formulation with ammonium polyphosphate and urea for applications on cotton and cotton-polyester blend fabric and Pekoflam PES, a mixture of cyclic di- and triphosphonates for finishing polyester.

### EXAMPLES 67 AND 68

| | Example | |
|---|---|---|
| | 67 | 68 |
| Sample | Cotton, gabardine, | Trevira polyester |
| Recipe | 200 g/m² | 220 g/m² |
| Pekoflam DPN 1 [g/l] | 350 | — |
| Pekoflam PES [g/l] | — | 400 |
| Cassurit HML (crosslinker) [g/l] | 60 | 60 |
| Phosphoric acid 85% [g/l] | 12 | 70 |
| Ammonia 25% [g/l] | | |
| Formulation to example 9 [g/l] | 18 | 20 |
| pH measured (pH paper) | about 1 | about 6 |
| Application data (padder; tenter) | | |
| Pick-up (g of liquor picked up:g of dry | 0.8 | 0.65 |
| textile) | | |
| | washing with soda ash | washing with wetter |
| After treatment | solution at 80° C. | at 60° C. |
| Drying conditions [° C.; s] | 120; 120 | 120; 120 |
| Curing conditions [° C.; s effective] | 160; 120 | 150; 60 |
| Example 9 formulation concentration [%] | 1.4 | 1.3 |
| | log kill rate for Staphylococcus aureus | |
| Tests after pretreatment of sample | ATCC 6538 to ASTM E 21-49 | |
| Original state (unwashed, unexposed) | >4.5 | >4.5 |
| 10 washes at 40° C. | >4.5 | >4.5 |
| 20 washes at 40° C. | >4.5 | 3.8 |

Typical examples for use of textiles finished as described above are clothing textiles, in particular workwear, uniforms, bedding, textile wallcoverings, seat covers, upholstered furniture and carpets, tablecloths, fabrics for umbrellas, sunshades and visual protection.

The applications of the formulation according to example 9 were also tested by means of exhaust processes. An attempt was made to apply said formulation to the basic substrates by means of exhaust processes. As the examples which follow show, outstanding results are surprisingly obtained.

### EXAMPLES 69 TO 71

| | Example | | |
|---|---|---|---|
| | 69 | 70 | 71 |
| Sample | Cotton, | Trevira | Polyamide |
| Recipe | gabardine, | polyester | jersey |
| | 200 g/m² | 220 g/m² | 160 g/m² |
| Sandozin MRN (wetter) [g/l] | 1.0 | 1.0 | 1.0 |
| Set pH with 80% acetic acid [pH] | 5 | 5 | 5 |
| Formulation to example 9 [in % | 1.0 | 1.0 | 1.0 |
| based on the mass of the textile] | | | |
| Liquor ratio | 1:10 | 1:10 | 1:10 |
| Exhaustion temperature [° C.] | 60 | 60 | 60 |
| Exhaustion time [minutes] | 45 | 45 | 45 |
| Drying conditions [° C.; s] | 120; 120 | 120; 120 | 120; 120 |
| Curing conditions [° C.; s] | 160; 90 | 160; 90 | 160; 90 |
| | log kill rate for | | |
| | Staphylococcus aureus | | |
| Tests after pretreatment of sample | ATCC 6538 to ASTM E 21-49 | | |
| Original state (unwashed, unexposed) | >5.0 | >5.0 | >5.0 |
| 10 washes at 40° C. | 4.5 | 4.6 | |
| 20 washes at 40° C. | 2.8 | 1.2 | 3.8 ? |
| 30 washes at 40° C. | 3.3 | 0.6 | >5.0 |

It was ascertained that the exhaust process can in principle be used with good results on the standard fabric types. The uses of textiles which have been finished by following this process are various. Exhaust processes are often used to finish knitted fabrics, in some instances when more or less made up into garments. This is done because knitted fabrics tend to distort on the tenter. At the same time, the exhaust process often includes further gray cloth conversion steps, such as dyeing, the addition of softeners and the like. Stockings, pantyhose, T-shirts, sweaters and sweatshirts are examples of articles finishable by following the process.

### EXAMPLE 72

A further series of tests was carried out on silk and a blend fabric composed of cotton and polyester, using silver salt +pinacryptol yellow, and good antimicrobial results were obtained not only with but also without binder (Appreton N 92111).

Preservation was still satisfactory after 20 wash cycles.

### EXAMPLE 73

Applications in the exhaust process, the standard industrial process for knitted fabrics and particularly for made-up goods such as socks or T-shirts, are decisively governed by the rate of exhaustion. It decides the yield and, on the other hand, the fate of the textile chemicals which remain in the exhaust liquor and are water pollutants and in turn all chemicals which are not degraded in the wastewater treatment stage and adversely impact the outfall. To determine the rate of exhaustion of the formulation according to example 9, the residual apparatus (BFA type Labomat from Mathis Werner AG, CH-8156 Oberhasli/Zurich), by means of atomic absorption spectroscopy.

The Exhaust Conditions were:
The mass ratio of liquor to textile was always 10:1
Substrates: CO is a bleached woven fabric of cotton (gabardine) having a basis weight of 198 g/m², PA is a white loomstate fabric of polyamide (jersey) having a basis weight of 160 g/m², PES is a white loomstate fabric of polyester (Trevira) having a basis weight of 220 g/m²,
The amount of the formulation according to example 9 used was always 0.5% or 0.8% based on the mass of the dry textile. This corresponds to a starting concentration of 5 or 8 ppm Ag⁺ respectively
The pH was adjusted to 4 to 5 with 80% acetic acid
The heating and cooling rate was 3° C. per minute in all cases
The exhaust temperature was 60° C. and samples for the tests with polyester were additionally finished by the high temperature (HT) process at 120° C.
Exhaustion times were 30 minutes at 60° C. and 20 minutes at 120° C., at the exhaustion temperature
The liquors were separated off after cooling and analyzed
The samples were rinsed once in cold water (from the municipal grid) for 2 minutes
The samples were dried on a tenter at 120° C. tenter temperature for two minutes.

Analytical Results from the Silver Assays

| | Example 9 | | | |
|---|---|---|---|---|
| | formulation | | | |
| | concentration | | | |
| | [%, based on | | Ag in liquor | |
| Substrate | mass of textile] | Temp. [° C.] | [ppm] | Yield [%] |
| CO | 0.5 | 60 | 1.2 | 76 |
| CO | 0.8 | 60 | 1.1 | 86 |
| PA | 0.5 | 60 | 0.3 | 94 |
| PA | 0.8 | 60 | 0.3 | 96 |
| PES | 0.5 | 60 | 0.9 | 82 |
| PES | 0.8 | 60 | 0.4 | 95 |
| PES | 0.5 | 120 | 0.5 | 90 |
| PES | 0.8 | 120 | 0.4 | 95 |

The samples were washed to EN ISO 6330 (6A) at 40° C. with the ECE 77 detergent and tested after 20, 30 and 50 wash cycles against Staphylococcus aureus ATCC 6538 by the shake flask test of ASTM E 21-49. In this test panel, all kill rate values were distinctly above 90% compared with the inoculum after 30 wash cycles. Except for the polyester fabric finished at 60° C., the kill rate values were still above 90% after 50 wash cycles.

Comparative tests with JMAC LP 10 gave no antibacterial effect on polyester after just 20 wash cycles and the concentration of silver in the exhaust liquor was in the range from 1 ppm (PA) to 4 ppm (PES and CO, both initial concentrations). The liquor from the application to

PES in the high temperature process still contained 3 ppm from initial concentrations of 7.5 or 12 ppm of Ag⁺ in the batch. The yield in the case of the application of the product according to example 9 is significantly better than in the case of the reference material which utilizes titanium dioxide as carrier for the silver compound. Despite the distinctly lower use level of silver compound, made up in a ratio of 3:2, at least equivalent and, on the sensitive substrate, even distinctly superior wash durabilities were measured.

All the examples which follow were carried out on manufacturing-scale machines. The amounts of textiles used in all cases corresponded to an amount for pilot tests, i.e., several tens of linear meters in the case of padded applications and around ten or more kilograms of fabric in the case of the exhaust processes. The examples involving socks were carried out using the standard production size for one lot. The washes were carried out to EN ISO 6330 by using the standardized colorfastness detergent ECE 77. In addition to the standard temperatures of 40 and 60° C., a specific wash program was programmed in to run at the washing and rinsing times of the 60° C. program, but involving heating up to 72° C. This is the highest washing temperature in a chamber of the industrial washer line used herein as reference for the experiments. The wash tests were discontinued after 100 cycles, since this is far above the values which are relevant in practice to the service life of most textiles and are even far above the values which the marketplace is currently demanding, although standards are on the increase.

Expectations with regard to the durability of the antibacterial finish range from 20 to 30 wash cycles and in special cases are equal to 50 wash cycles. 100 wash cycles are, if at all, only of interest for the hotel/catering and care sectors, although here the washes are very much shorter in duration and mechanically gentler than the wash standard which follows the customary European household wash.

### EXAMPLES 74 AND 75

30 kg of ready-constructed black socks of cotton-polyester are loaded into a Lavatec spray dryer. A mixture of 900 g of Hydroperm HV, 600 g of Hydroperm RPU and 200 g of the formulation according to example 9 in 10 liters of water are sprayed onto the socks by means of a steam jet, from the spray head mounted in the axis of rotation, into the running horizontal rotary drum. The socks are subsequently dried in the drum. The socks are tested after 20 and 30 wash cycles against Staphylococcus aureus ATCC 6538 by the shake flask test of ASTM E 21-49. The kill rate was still above 99% after 30 wash cycles.

The same test was carried out with a silver product on titanium oxide and otherwise the same recipe in the same experimental set-up.—The product was impossible to spray homogenously using the steam jet. Since the process is not suitable for such products, the test was terminated and the samples were not further tested.

To 80 kg of ready-constructed gray socks of cotton-polyester in a cage in an exhaust bath holding 1000 liters of water is added a mixture of 1 kg of the formulation according to example 9 in 10 liters of water. As the liquor circulates, i.e., at the bottom end of the tank, i.e., underneath the cage, the liquor is removed and pumped by a heat exchanger to the upper level, where the liquor flows back onto the goods via a distributor, is heated to 60° C., maintained at 60° C. for 15 minutes and subsequently 2.4 kg of Hydroperm HV and 1.6 kg of Hydroperm RPU in 15 liters of water are added and the liquor is maintained at a constant temperature of 60° C. for a further 30 minutes while it continues to circulate. The liquor is subsequently dropped and the g s are rinsed with cold water in the same apparatus, the rinse water is likewise removed, and the goods are discharged, whizzed and subsequently dried.

The socks are tested after 20 and 30 wash cycles against Staphylococcus aureus ATCC 6538 by the shake flask test of ASTM E 21-49. The kill rate was still above 99% after 30 wash cycles with this finishing method also.

### EXAMPLE 76

12 kg of a violet woven fabric composed of 80% polyamide and 20% Lycra is treated in a jet with a liquor composed of 180 g of the formulation according to example 9 in 80 liters of water, at 60° C. for 30 minutes. After cooling, the water is dropped. Fresh water is added for rinsing and is likewise dropped after 5 minutes. The woven fabric is dried at 150° C. and a linear speed of 10 meters per minute on a tenter which has six heating zones and is 18 meters in length. This textile is used to carry out wash tests at 40, 60 and 72° C., and the samples are dried after 1, 3, 5, 10, 20, 40, 50, 60, 80 and 100 wash cycles and tested. After 100 wash cycles, the experiment is discontinued. All samples give a kill rate of at least 90% when tested against Staphylococcus aureus ATCC 6538 by the shake flask test of ASTM E 21-49.

### EXAMPLE 77

Red knitted fabric composed of polyester (for sports shirts) is finished with 1.5% of the formulation according to example 9, 0.03% of Hostapal MRN wetting agent and 4.0% of Solusoft MW softener and 0.5% of Velustrol P40 softener, by padding. This is followed by drying and curing on a tenter at 150° C.

The samples were tested after 50 and after 100 wash cycles at 72° C. against Staphylococcus aureus ATCC 6538 by the shake flask test of ASTM E 21-49. The kill rate was above 99% for both samples.

### EXAMPLE 78

The same recipe as in example 76 but additionally with 5.0% of Appretan N 92111 soft acrylate binder was applied to the same substrate in the same process.

The samples were tested after 50 and after 100 wash cycles at 72° C. against Staphylococcus aureus ATCC 6538 by the shake flask test of ASTM E 21-49. The kill rate was distinctly above 99% for both samples.

### EXAMPLES 79 AND 80

A dark blue polyester textile (for leisure wear) was finished with 1.2% of the formulation according to example 9 once with and once without 4.0% of Appretan N 92111, by padding. The fabric is dried at 150° C. and a linear speed of 10 meters per minute on a tenter which has six heating zones and is 18 meters in length.

The samples were tested after 50 and after 100 wash cycles at 72° C. against Staphylococcus aureus ATCC 6538 by the shake flask test of ASTM E 21-49. The kill rate was very distinctly above 99% for all samples.

### EXAMPLE 81

An application at the very long liquor ratio of 40:1 was carried out in an exhaust process in a jet on a blue textile composed of polyamide with elastane. At pH 5 (set with acetic acid), 1.2% (always based on the mass of the dry unfinished textile) of the formulation according to example 9 was applied at 60° C.

The samples were tested after 50 and after 100 wash cycles at 72° C. against Staphylococcus aureus ATCC 6538 by the shake flask test of ASTM E 21-49. The kill rate was still distinctly above 99% even with these samples.

1. A process for finishing fibers and/or textiles with an antimicrobially active component comprising
contacting a fiber or textile with an antimicrobially active component comprising
at least one desensitized silver component and
optionally, at least one further antimicrobial component,
wherein the at least one desensitized silver component is desensitized by a desensitizing component,
wherein the desensitizing component comprises at least one compound selected from the group of the quinoline derivatives.

2. The process as claimed in claim 1, characterized in that the at least one silver component comprises a silver salt.

3. The process as claimed in claim 1, characterized in that the at least one silver component comprises a silver salt formed in situ and the at least one desensitizing component comprises pinacryptol yellow.

4. The process as claimed in claim 1, characterized in that the at least one silver component comprises a silver salt and the at least one desensitizing component comprises at least one quinoline derivative and additionally at least one benzotriazole derivative.

5. The process as claimed in claim 1, characterized in that the at least one silver component is present in an amount ranging from about 0.0001% by weight to about 1.5% by weight, based on the total weight of the fibers or textiles.

6. The process as claimed in claim 1, characterized in that the at least one quinoline derivative is present in an amount ranging from about 0.1 ppm to about 500 ppm, based on the total weight of the fibers or textiles.

7. The process as claimed in claim 1, characterized in that the at least one silver component comprises a water-insoluble silver salt and the at least one desensitizing component comprises at least one quinoline derivative and at least one benzotriazole derivative,
wherein said at least one benzotriazole derivative is present in an amount ranging from about 0.5 ppm to about 2500 ppm, based on the total weight of the fibers or textiles.

8. The process as claimed in claim 7, characterized in that the water-insoluble silver salt comprises at least one salt selected from the group of the chlorides, bromides, iodides, sulfates and tosylates.

9. The process as claimed in claim 7, characterized in that the water-insoluble silver salt comprises a silver chloride prepared in situ from silver nitrate and metal chloride.

10. The process as claimed in claim 1, characterized in that the at least one desensitizing component comprises pinacryptol yellow as the sole component or the at least one desensitizing component comprises a combination of pinacryptol yellow with at least one other desensitizing component.

11. The process as claimed in claim 1, characterized in that the process for finishing the fibers and/or textiles comprises a padding process, exhaust process, foam application process, coating process or spraying process.

12-19. (canceled)

20. An antimicrobial preparation for finishing fibers and/or textiles, comprising an antimicrobially active component comprising
at least one silver component,
at least one desensitizing component,
and optionally, at least one auxiliary and additive material,
wherein the at least one desensitizing component comprises at least one compound selected from the group of the quinoline derivatives.

21. The preparation as claimed in claim 20, characterized in that said antimicrobially active component comprises about 0.01% to about 10% of the at least one silver component and about 0.001% to about 2% of pinacryptol yellow.

22. Antimicrobially finished fibers and textiles obtained by following a process as claimed in claim 1.

23. The antimicrobially finished fibers and textiles as claimed in claim 22, characterized in that they comprise woven fabrics, knitted fabrics, fibrous nonwoven webs or yarns.

24. A method of protecting fibers and textiles against attack by bacteria comprising the step of contacting a fiber or textile with a preparation as claimed in claim 20.

25. A method of claim 24, characterized in that the at least one silver component comprises a silver salt and the at least one desensitizing component comprises at least one quinoline derivative and at least one benzotriazole derivative for protecting fibers and textiles against attack by bacteria.
